(19) United States
(12) Patent Application Publication
(10) Pub. No.: US 2019/0131768 A1
(43) Pub. Date: May 2, 2019

(54) LIGHT MONITORING MECHANISM, EXTERNAL RESONATOR-TYPE LASER LIGHT SOURCE, TUNABLE LASER DEVICE, AND OPTICAL WAVEGUIDE FILTER

(71) Applicant: NEC Corporation, Minato-ku, Tokyo (JP)

(72) Inventor: Naoki KOBAYASHI, Tokyo (JP)

(73) Assignee: NEC Corporation, Minato-ku, Tokyo (JP)

(21) Appl. No.: 16/091,171

(22) PCT Filed: Mar. 30, 2017
(86) PCT No.: PCT/JP2017/013245

§ 371 Date: Oct. 4, 2018

(30) Foreign Application Priority Data
Apr. 21, 2016 (JP) 2016-085209

(51) Int. Cl. H01S 5/0683; H01S 5/14; H01S 5/50; H04J 14/02; H04B 10/079; H04B 10/61; H04B 10/50

(52) U.S. Cl. CPC H01S 5/0683; H01S 5/142; H01S 5/50; H04B 10/503; H04B 10/07957; H04B 10/615; H04J 14/0227

(57) ABSTRACT

A light monitoring mechanism for monitoring light in an optical circuit (10) including a loopback mirror (12) in loopback shape to which a linear optical waveguide (11) is connected has a structure in which a tap port (15) in loopback or loop shape is placed in close proximity to a position on the loopback mirror (12) where optical lengths from a connection point between the loopback mirror (12) and the optical waveguide (11) when light travels clockwise and when light travels counterclockwise are equal, which enables extraction a part of light from the loopback mirror (12) to the tap port (15) as monitoring light without optical loss. A light monitoring mechanism having a structure that minimizes the occurrence of optical loss when extracting light for monitoring is thereby provided.

### TECHNICAL FIELD

The present invention relates to a light monitoring mechanism, an external resonator-type laser light source, a wavelength tunable laser device, and an optical waveguide filter and, particularly, to a light monitoring mechanism, an external resonator-type laser light source, a wavelength tunable laser device, and an optical waveguide filter in which a tap with reduced loss (lossless tap) is achieved.

### BACKGROUND ART

A digital coherent communication system is a communication system that can transmit a large volume of information by wavelength multiplexing in one optical fiber. A wavelength tunable laser device that is used in an existing digital coherent communication system is equipped with two light sources, one for transmission and the other for reception, as tunable local oscillator light sources. Each of the light sources is equipped with a light monitoring mechanism for monitoring the wavelength, output intensity, S/N ratio (Signal-to-Noise Ratio) and the like of emitted light.

Further, mounting only one light source, instead of two light sources, on a future digital coherent communication system to achieve downsizing and lower power consumption is being considered. However, since the number of light sources is reduced from two to one, a high output operation is required for the one light source, and the monitoring accuracy needs to be further improved.

An example of an external resonator-type laser light source that includes a semiconductor optical amplifier and a waveguide-type optical circuit is described hereinafter by way of illustration. FIGS. 3A and 3B are structural diagrams showing an exemplary external resonator-type laser light source having a simple structure without a light monitoring mechanism. FIG. 3A shows the structure of the external resonator-type laser light source. FIG. 3B is a view showing, by arrows, a light path and traveling direction in the external resonator-type laser light source having the structure shown in FIG. 3A. In the external resonator-type laser light source, an external optical filter and a semiconductor optical amplifier (SOA) are spatially-combined using a lens to form a resonator structure.

With such a resonator structure, it is possible to use a high-performance optical filter and achieve a relatively wide wavelength tunable range.

As shown in FIG. 3A, the external resonator-type laser light source includes an optical circuit 10A and a semiconductor optical amplifier 20. The optical circuit 10A includes an optical waveguide 11 and a loopback mirror 12 in loopback shape. The loopback mirror 12 functions as a ring resonator, and its round-trip length is determined by the wavelength of input light. As shown in FIG. 3B, light travels around in the semiconductor optical amplifier 20 and the optical circuit 10A and is output as amplified light output.

To be specific, light in the forward path that is emitted by applying a current to the semiconductor optical amplifier 20 is output from the semiconductor optical amplifier 20 to the optical circuit 10A. After that, as shown in FIG. 3B, the light from the semiconductor optical amplifier 20 travels through the optical waveguide 11 in the optical circuit 10A and then branches in two directions, clockwise and counterclockwise, at a connection point with the loopback mirror 12. Each of the lights branched in two directions travels through the loopback mirror 12 and loops back to the optical waveguide 11 through the loopback structure. The semiconductor optical amplifier 20 functions as an amplifier for light that travels in one direction toward the light output side. The semiconductor optical amplifier 20 is coated with an antireflection coating at its end face. The light in the return path is amplified by the semiconductor optical amplifier 20 while heading to the end face. The light in the return path that is looped back by the loopback mirror 12 is input to and amplified by the semiconductor optical amplifier 20, and then a part of the light passes through the end face and is output to the outside as light output. A part of the light in the return path amplified by the semiconductor optical amplifier 20 is reflected by the end face, becomes light in the forward path and enters the loopback mirror 12 through the optical waveguide 11. In this manner, in the external resonator-type laser light source in FIG. 3, light in the return path that has been looped back through the optical waveguide 11 is amplified by the semiconductor optical amplifier 20, and a part of the light in the return path is reflected by the end face on the light output side, and returns again after traveling through the optical waveguide 11 and the loopback mirror 12 repeatedly. Such a structure having the semiconductor optical amplifier 20, the optical waveguide 11 and the loopback mirror 12 enables lasing and outputs a part of laser light as output light from the end face to the outside.

An external resonator-type laser light source according to related art, which has a structure equipped with a light monitoring mechanism is described hereinafter. FIGS. 4A and 4B are structural diagrams showing an exemplary external resonator-type laser light source according to related art, which is equipped with a light monitoring mechanism. FIG. 4A shows the structure of the external resonator-type laser light source, and FIG. 4B is a view showing, by arrows, a light path and traveling direction in the external resonator-type laser light source having the structure shown in FIG. 4A.

As shown in FIG. 4A, an optical circuit 10B further includes a tap port 17 (i.e., optical waveguide for monitoring) as an optical tap for monitoring the wavelength, intensity and the like of light (see Patent Literatures 1 and 2), which is different from the optical circuit 10A in FIG. 3A. Note that the optical tap means a part or an operation of extracting light. The tap port 17 is formed in a curved shape, a part of which comes close to the optical waveguide 11 from the semiconductor optical amplifier 20 to the loopback mirror 12 so as to branch and extract a part of light in the return path (about several %).

Thus, as shown in FIG. 4B, a part of light in the return path heading to the loopback mirror 12 is extracted to the tap port 17 (optical waveguide for monitoring) and output as monitoring light output through an optical waveguide on a monitor port 18 side. X

### CITATION LIST

### Patent Literature

PTL1: Japanese Unexamined Patent Application Publication No. 2015-212687

PTL2: International Patent Publication No. WO2013/114578

### SUMMARY OF INVENTION

### Technical Problem

However, according to related art, excessive loss occurs when extracting a part of light for monitoring in a light monitoring mechanism for monitoring the wavelength, output intensity, S/N ratio (Signal-to-Noise Ratio) and the like of light. It is important to reduce such loss. In order to achieve high output operation, it is required that optical loss in a light source is as small as possible. Particularly, in a structure having one light source, instead of two light sources, for the purpose of downsizing, it is required to reduce optical loss to the smallest possible level in the light monitoring mechanism in order to achieve high output operation.

However, according to related art, the tap port 17 having the structure as shown in FIG. 4 is used as the light monitoring mechanism, and a part of light in the return path that is looped back from the loopback mirror 12 and travels through the optical waveguide 11 toward the semiconductor optical amplifier 20 is also extracted to the tap port 17, then travels toward an optical waveguide on a dump port 19 side in the opposite direction to the monitor port 18, and is discarded as unintended monitoring light, i.e., ineffective light, which causes the occurrence of optical loss. Thus, a problem to be solved in an optical device that includes the light monitoring mechanism according to related art as shown in FIG. 4 is to minimize unnecessary loss of light in light monitoring.

### Object of Present Invention

The present invention has been accomplished to solve the above problem and an object of the present invention is to provide a light monitoring mechanism, an external resonator-type laser light source, a wavelength tunable laser device, and an optical waveguide filter having a structure that minimizes the occurrence of optical loss when extracting light for monitoring.

### Solution to Problem

To solve the above problem, the light monitoring mechanism, the external resonator-type laser light source, the wavelength tunable laser device, and the optical waveguide filter according to the present invention mainly have the following characteristic structure.

(1) A light monitoring mechanism according to the present invention includes a loopback mirror in loopback shape to which an optical waveguide is connected, and a tap port in loopback or loop shape placed in close proximity to a position on the loopback mirror where optical lengths from a connection point between the loopback mirror and the optical waveguide when light travels clockwise and when light travels counterclockwise are equal, wherein a part of light from the loopback mirror is extracted to the tap port as monitoring light.

(2) An external resonator-type laser light source according to the present invention is an external resonator-type laser light source including a semiconductor optical amplifier and a waveguide-type optical circuit, wherein the light monitoring mechanism described in the above (1) is used as a light monitoring mechanism for monitoring light in the optical circuit.

(3) A wavelength tunable laser device according to the present invention is a wavelength tunable laser device that emits laser light with tunable wavelength, wherein the external resonator-type laser light source described in the above (2) is used as a light source that emits the laser light.

(4) An optical waveguide filter according to the present invention is an optical waveguide filter that separates wavelength-multiplexed light by wavelength with use of an optical waveguide filter, wherein the light monitoring mechanism described in the above (1) is used as a light monitoring mechanism for monitoring the wavelength-multiplexed light input to the optical waveguide filter.

### Advantageous Effects of Invention

The light monitoring mechanism, the external resonator-type laser light source, the wavelength tunable laser device, and the optical waveguide filter according to the present invention have the following advantageous effects.

Specifically, according to the present invention, because a tap structure in loopback or loop shape is employed as a light monitoring mechanism for monitoring the intensity, wavelength, S/N ratio and the like of light, it is possible to extract monitoring light without the occurrence of unnecessary optical loss.

### BRIEF DESCRIPTION OF DRAWINGS

FIG. 1A is a structural diagram showing an exemplary light monitoring mechanism according to the present invention.

FIG. 1B is a structural diagram showing an exemplary light monitoring mechanism according to the present invention.

FIG. 2 is a structural diagram showing an exemplary structure of an optical waveguide filter according to the present invention.

FIG. 3A is a structural diagram showing an exemplary external resonator-type laser light source having a simple structure without a light monitoring mechanism.

FIG. 3B is a structural diagram showing an exemplary external resonator-type laser light source having a simple structure without a light monitoring mechanism.

FIG. 4A is a structural diagram showing an exemplary external resonator-type laser light source according to related art with a light monitoring mechanism.

FIG. 4B is a structural diagram showing an exemplary external resonator-type laser light source according to related art with a light monitoring mechanism.

### DESCRIPTION OF EMBODIMENTS

A preferred embodiment of a light monitoring mechanism, an external resonator-type laser light source, a wavelength tunable laser device, and an optical waveguide filter according to the present invention is described hereinafter with reference to the attached drawings. Note that, although a light monitoring mechanism and an optical waveguide filter according to the present invention are described in the following description, an external resonator-type laser light source that includes a semiconductor optical amplifier and a waveguide-type optical circuit, or a wavelength tunable laser device that emits laser light with tunable wavelength which is used in a digital coherent communication system may have a structure with such a light monitoring mechanism as a matter of course. Further, the reference symbols in each of the drawings described hereinafter are shown by way of illustration only for easier understanding and are not intended to limit the invention to those illustrated in the drawings.

### (Feature of Present Invention)

Prior to describing an embodiment of the present invention, an overview of the feature of the present invention will be given first. The principal feature of the present invention is to have a tap structure in a loopback or loop shape as a light monitoring mechanism for monitoring the intensity, wavelength, S/N ratio and the like of light. Specifically, the principal feature is to place an optical tap in a loopback or loop shape in close proximity to a loopback mirror unit in an optical circuit and thereby implement a light monitoring mechanism having a structure capable of monitoring optical power with reduced optical loss.

To be more specific, the principal feature is to employ a light monitoring mechanism having the following structure.

Specifically, the feature is that, along with a loopback mirror including an optical waveguide in a loopback shape, an optical tap including a linear optical waveguide for guiding guided light to an open end of an optical circuit and an optical waveguide (tap port) in loopback or loop shape is placed at a position on the loop mirror where the optical lengths from one end on the loopback mirror to which the optical waveguide for inputting and outputting guided light to and from the loopback mirror is connected when light travels clockwise around the loop and when light travels counterclockwise around the loop are equal. Further, regarding the optical tap, a position on the optical waveguide (tap port) where the optical lengths from one end on the optical waveguide (tap port) in a loopback or loop shape to which a linear optical waveguide for guiding guided light to the open end of the optical circuit is connected when light travels clockwise around the loop and when light travels counterclockwise around the loop are equal is placed in closest proximity to the loopback mirror.

This eliminates the need to place an unnecessary opening (dump port) in an optical circuit as a light monitoring mechanism for monitoring the wavelength, output intensity, S/N ratio and the like of light, and it is thereby possible to suppress the occurrence of excessive optical loss.

Such a light monitoring mechanism can be suitably applied to an external resonator-type laser light source composed of an optical waveguide with a loopback mirror and a semiconductor optical amplifier, a tunable filter and the like. For example, in the external resonator-type laser light source, by placing the light monitoring mechanism according to the present invention (i.e., an optical tap structure in loop shape (or in loopback shape)) along with the loopback mirror in a waveguide-type optical circuit, it is possible to implement a light source where optical loss when extracting monitoring light does not occur.

### Embodiment According to the Present Invention

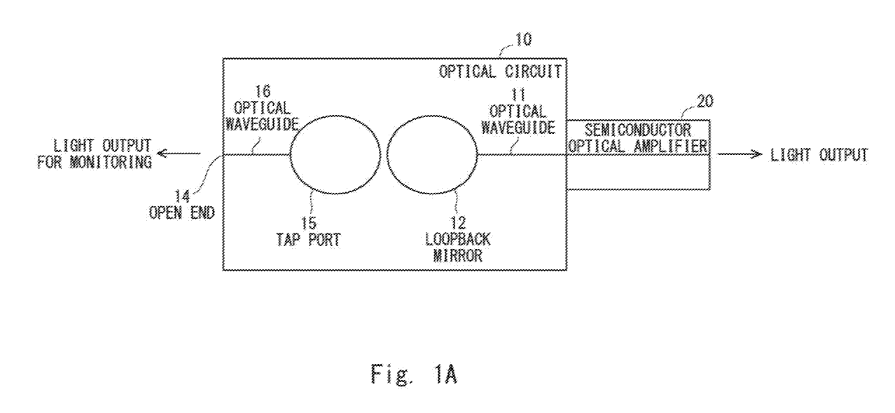

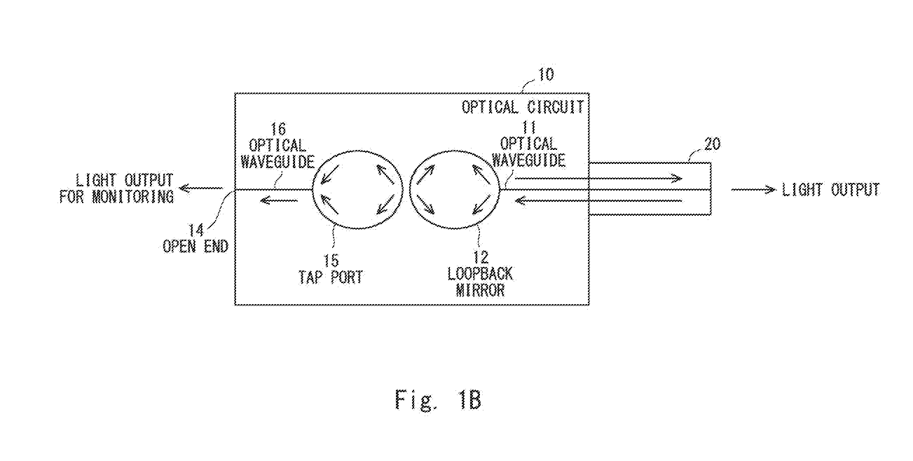

An embodiment of a light monitoring mechanism according to the present invention is described hereinafter with reference to FIG. 1. FIGS. 1A and 1B are structural diagrams showing an exemplary light monitoring mechanism according to the present invention, FIG. 1A showing an example of the structure of the light monitoring mechanism, and FIG. 1B being a view showing, by arrows, a light path and traveling direction in the light monitoring mechanism in FIG. 1A.

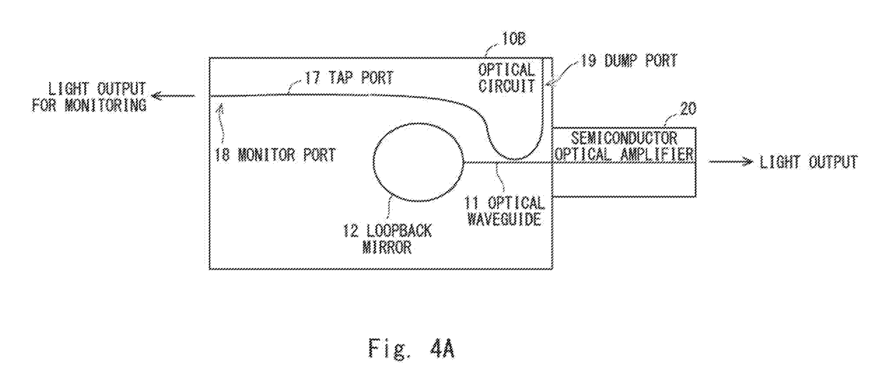

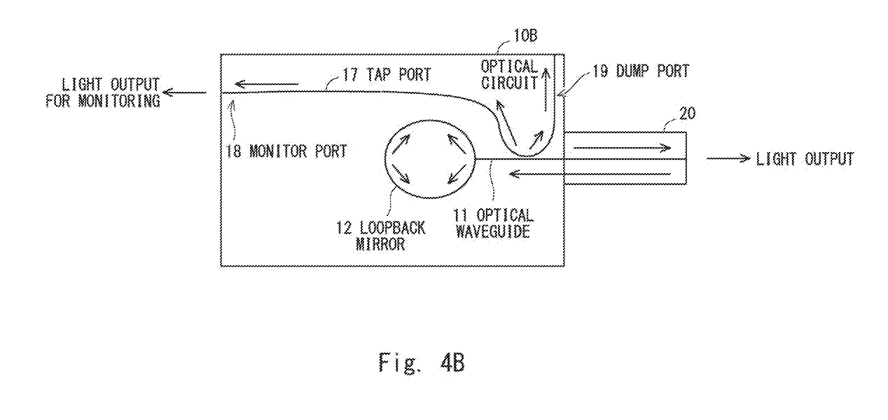

As shown in FIG. 1A, the feature of the light monitoring mechanism according to the present invention is to place an optical tap in a loop or loopback shape in close proximity to a loop mirror having a loopback structure. This light monitoring mechanism is placed in an optical device that includes an optical circuit 10 and a semiconductor optical amplifier 20, just as shown in FIG. 4A. The optical circuit 10 has a structure including a linear optical waveguide 11, a loopback mirror 12 in a loop shape and further including, as an optical tap for light monitoring, a tap port 15 in a loop shape (or a loopback shape) and a linear optical waveguide 16. The optical tap means a part or an operation of extracting light. The optical tap for light monitoring includes the tap port 15 in a loop shape (or a loopback shape) and the optical waveguide 16 in a linear shape, which is different from the light monitoring mechanism according to related art shown in FIG. 4. In the light monitoring mechanism according to related art shown in FIG. 4, the tap port 17 in a curved shape, a part of which comes close to the optical waveguide 11, is used as the optical tap for light monitoring.

The round-trip length (optical length) of the loopback mirror 12 that is composed of a looped optical waveguide is determined by the wavelength of input light, and it functions as a ring resonator. The tap port 15 is an optical waveguide in a loop or loopback shape whose round-trip length (optical length) is the same as the round-trip length of the loopback mirror 12 on the monitored side, and it is connected to the linear optical waveguide 16 that guides guided light (monitoring light) to an open end 14 of the optical circuit 10.

The tap port 15 is placed in close proximity to the loopback mirror 12 on the monitored side in the circuit 10. The position of the tap port 15 that is placed in close proximity to the loopback mirror 12 is where the optical lengths from a connection position of the optical waveguide 11 for inputting and outputting guided light to and from the loopback mirror 12 when light travels clockwise around the loopback mirror 12 and when light travels counterclockwise around the loopback mirror 12 are equal (i.e., the position on the loopback mirror 12 opposite to the connection position of the optical waveguide 11).

Further, the tap port 15 is placed so that the position where the optical lengths from a connection position with the optical waveguide 16 when light travels clockwise around the tap port 15 and when light travels counterclockwise around the tap port 15 are equal (i.e., the position on the tap port 15 opposite to the connection position of the optical waveguide 16) is in closest proximity to the loopback mirror 12 on the monitored side. In other words, the linear optical waveguide 16 is connected to the position on the tap port 15 where the optical lengths from the position on the tap port 15 in closest proximity to the loopback mirror 12 on the monitored side when light travels clockwise and when light travels counterclockwise are equal. The light monitoring mechanism in which the loopback mirror 12, the tap port 15 and the optical waveguide 16 are optically connected in this manner can combine monitoring light that travels clockwise around the tap port 15 and monitoring light that travels counterclockwise around the tap port 15 at a connection point on the tap port 15 to which the optical waveguide 16 is connected, and extract the light to the outside through the optical waveguide 16 and the open end 14.

By using the light monitoring mechanism in which the tap structure is in a loop or loopback shape as described above, there is no need to place a dump port, and it is thereby possible to monitor the output intensity, wavelength and the like of laser light from an external resonator-type laser light source composed of a semiconductor optical amplifier and a waveguide-type optical circuit having a loopback mirror, for example, without the occurrence of optical loss.

### (Description of Operation of Embodiment)

An example of the operation of the light monitoring mechanism shown in FIG. 1A is described with reference to FIG. 1B.

As shown in FIG. 1B, light to be monitored travels around in the semiconductor optical amplifier 20 and the optical circuit 10 and is output as amplified light output. To be specific, light in the forward path travels through the semiconductor optical amplifier 20 and is input to the optical circuit 10.

After that, as shown in FIG. 1B, the light from the semiconductor optical amplifier 20 travels through the optical waveguide 11 in the optical circuit 10 and then branches in two directions, clockwise and counterclockwise, at a connection point with the loopback mirror 12. Each of the light travels through the loopback mirror 12, passes through the position opposite to the connection position of the optical waveguide 11 (connection position with the tap port 15), and returns to the connection point with the optical waveguide 11. The two returned light are combined at the connection point with the optical waveguide 11 and loop back to the optical waveguide 11.

At this time, a part of both of the clockwise light and the counterclockwise light is extracted as monitoring light to the tap port 15 placed in close proximity to the position on the loopback mirror 12 opposite to the connection position of the optical waveguide 11 (i.e., the position where the optical lengths when light travels clockwise around the loopback mirror 12 and when light travels counterclockwise are equal). Specifically, a part of the light that has traveled clockwise around the loopback mirror 12 is extracted as monitoring light that travels counterclockwise around the tap port 15 in loopback shape, and a part of the light that has traveled counterclockwise around the loopback mirror 12 is extracted as monitoring light that travels clockwise around the tap port 15 in loopback shape.

On the other hand, light in the return path that has been looped back to the optical waveguide 11 is input again to the semiconductor optical amplifier 20, amplified and output to the outside as light output. Note that, in the semiconductor optical amplifier 20, a part of light in the return path is reflected by the end face on the light output side, and returns again after traveling through the optical waveguide 11 and the loopback mirror 12 repeatedly for lasing, and the light is output as amplified light output from the semiconductor optical amplifier 20 to the outside.

On the other hand, each of the two monitoring light extracted to the tap port 15, which is, the monitoring light that travel around in two directions, clockwise and counterclockwise, travels around the tap port 15 in loopback shape to the position opposite to the position on the tap port 15 in closest proximity to the loopback mirror 12 on the monitored side (i.e., the position where the optical lengths when light travels clockwise around the tap port 15 and when light travels counterclockwise around the tap port 15 are equal). At this opposite position, the two monitoring light are combined, travel through the optical waveguide 16 that is connected to this opposite position, is output as light output for monitoring from the open end 14 of the optical circuit 10, and further output to the outside from a waveguide substrate on which the monitoring mechanism is mounted.

The two monitoring light are combined at the connection point of the tap port 15 with the optical waveguide 16, and because they are combined at the position where the optical lengths from the position at which a part of the light is extracted as monitoring light from the loopback mirror 12 on the monitored side when light travels clockwise around the tap port 15 and when light travels counterclockwise around the tap port 15 are equal, the two monitoring light have exactly the same optical intensity and phase, and therefore they are combined without the occurrence of optical loss. Note that, because optical loss occurs if the optical intensity and phase of the two monitoring light are different at the position where those light are combined, the position and direction of placing the tap port 15 are preferably as accurate as possible. Further, it is important that the optical properties including an optical loss rate and an optical phase shift rate are completely the same between the optical waveguides in the clockwise and counterclockwise directions in each of the optical waveguides of the tap port 15 in loopback shape and the loopback mirror 12.

Because the light monitoring mechanism in which the structure of the tap port 15 is in loopback or loop shape as described above is employed, the dump port 19 as shown in FIG. 4 is no longer placed, and optical loss does not occur when extracting monitoring light. It is thereby possible to monitor the output intensity, wavelength and the like of laser light from the external resonator-type laser light source composed of the semiconductor optical amplifier 20 and the waveguide-type optical circuit 10 having the loopback mirror 12 with no optical loss. Note that, if the tap port structure has a shape other than the above-described loopback shape, the intensity of monitoring light differs depending on the traveling direction of monitoring light, which causes loss to occur at the position where the light are combined.

### (Description of Effects of Embodiment)

As described in detail above, because a tap structure in loopback or loop shape is employed as a light monitoring mechanism for monitoring the intensity, wavelength, S/N ratio and the like of light in this embodiment, it is possible to extract monitoring light without the occurrence of unnecessary optical loss.

### (Embodiment of Optical Waveguide Filter)

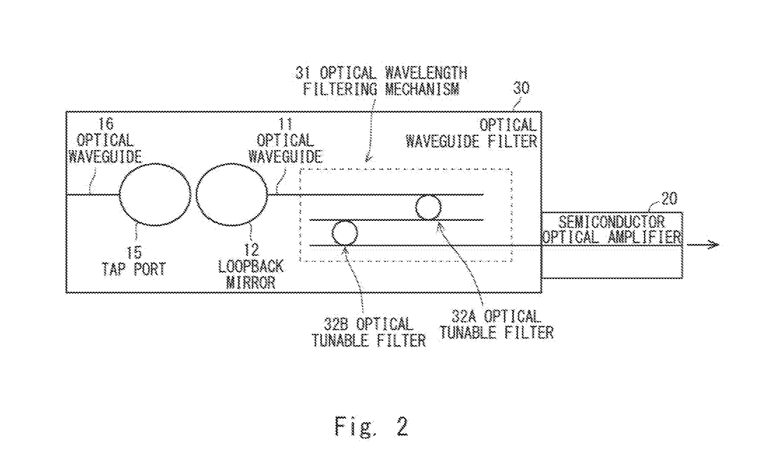

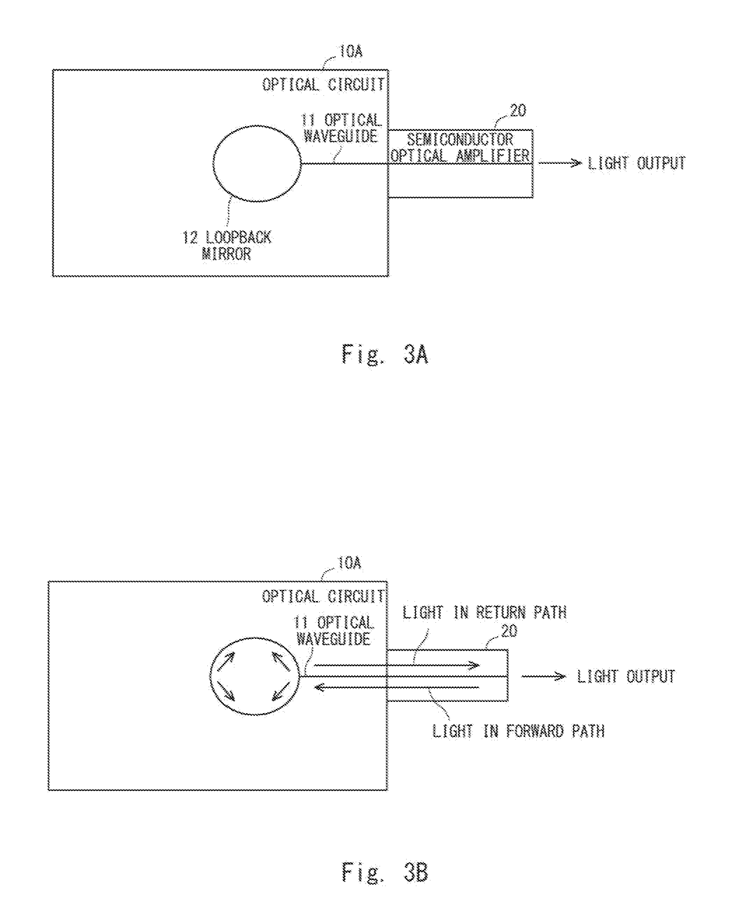

An embodiment of an optical waveguide filter that has a mechanism for extracting guided light depending on wavelength is described hereinafter with reference to FIG. 2. FIG. 2 is a structural diagram showing an example of the structure of an optical waveguide filter according to the present invention, and it shows an example of the structure of an optical waveguide filter that includes an optical tunable filter for separating and extracting only a specific tunable wavelength as an optical wavelength filtering mechanism that separates wavelength-multiplexed light by wavelength.

In the optical waveguide filter, it has become increasingly important to have a mechanism for monitoring and controlling the state (wavelength, intensity, S/N ratio etc.) of a light signal. Therefore, it is a promising trend to employ the structure of the optical waveguide filter 30 having the light monitoring mechanism as shown in FIG. 2, for example. Note that, although an optical waveguide filter composed of an optical tunable filter as an optical wavelength filter is described in this example, the present invention is not limited to such a case, and an optical fixed-wavelength filter may be used as a matter of course.

The optical waveguide filter 30 shown in FIG. 2 has a structure that includes two stages of optical tunable filters 32A and 32B as an optical wavelength filtering mechanism 31, and further includes an optical waveguide 11 and a loopback mirror 12. Further, as a light monitoring mechanism, a tap port 15 in loop or loopback shape to which a linear optical waveguide 16 is connected is placed in close proximity to the position on the loopback mirror 12 opposite to a connection point of the optical waveguide 11 (i.e., the position where the optical lengths from the connection point of the optical waveguide 11 when light travels clockwise around the loopback mirror 12 and when light travels counterclockwise around the loopback mirror 12 are equal) in this structure. In other words, the optical waveguide filter 30 has the optical wavelength filtering mechanism 31 that separates wavelength-multiplexed light by wavelength and employs the light monitoring mechanism shown in FIG. 1 as the light monitoring mechanism.

While the invention has been particularly shown and described with reference to embodiments thereof, the invention is not limited to these embodiments. It will be understood by those of ordinary skill in the art that various changes in form and details may be made therein without departing from the spirit and scope of the present invention as defined by the claims.

This application is based upon and claims the benefit of priority from Japanese patent application No. 2016-085209 filed on Apr. 21, 2016, the disclosure of which is incorporated herein in its entirety by reference.

### REFERENCE SIGNS LIST

10 OPTICAL CIRCUIT
10A OPTICAL CIRCUIT
10B OPTICAL CIRCUIT
11 OPTICAL WAVEGUIDE
12 LOOPBACK MIRROR
14 OPEN END
15 TAP PORT
16 OPTICAL WAVEGUIDE
17 TAP PORT
18 MONITOR PORT
19 DUMP PORT
20 SEMICONDUCTOR OPTICAL AMPLIFIER
30 OPTICAL WAVEGUIDE FILTER
31 OPTICAL WAVELENGTH FILTERING MECHANISM
32A OPTICAL TUNABLE FILTER
32B OPTICAL TUNABLE FILTER

What is claimed is:

1. A light monitoring mechanism comprising:
a loopback mirror in loopback shape to which an optical waveguide is connected; and
a tap port in a loopback or loop shape placed in close proximity to a position on the loopback mirror where optical lengths from a connection point between the loopback mirror and the optical waveguide when light travels clockwise and when light travels counterclockwise are equal,
wherein a part of light from the loopback mirror is extracted to the tap port as monitoring light.

2. The light monitoring mechanism according to claim 1, wherein
an optical waveguide is connected to a position on the tap port where optical lengths from a position on the tap port in closest proximity to the loopback mirror when light travels clockwise and when light travels counterclockwise are equal, and
the monitoring light traveling clockwise around the tap port and the monitoring light traveling counterclockwise around the tap port are combined at a connection point on the tap port to which the optical waveguide is connected, and extracted to an outside through the optical waveguide as light output for monitoring.

3. The light monitoring mechanism according to claim 1, wherein
optical properties including an optical loss rate and an optical phase shift rate of an optical waveguide running clockwise around the loopback mirror are the same as those of an optical waveguide running counterclockwise around the loopback mirror from a connection point with the optical waveguide, and
optical properties including an optical loss rate and an optical phase shift rate of an optical waveguide running clockwise are the same as those of an optical waveguide running counterclockwise from a position on the tap port in closest proximity to the loopback mirror.

4. An external resonator-type laser light source comprising a semiconductor optical amplifier and a waveguide-type optical circuit, wherein the light monitoring mechanism according to claim 1 is used as a light monitoring mechanism for monitoring light in the optical circuit.

5. A wavelength tunable laser device that emits laser light with a tunable wavelength, wherein the external resonator-type laser light source according to claim 4 is used as a light source that emits the laser light.

6. An optical waveguide filter that separates wavelength-multiplexed light by a wavelength with use of an optical waveguide filter, wherein the light monitoring mechanism according to claim 1 is used as a light monitoring mechanism for monitoring the wavelength-multiplexed light input to the optical waveguide filter.
